(19) United States
(12) Patent Application Publication
(10) Pub. No.: US 2012/0222742 A1
(43) Pub. Date: Sep. 6, 2012

(54) COMPOUND THIN FILM SOLAR CELL AND METHOD FOR MANUFACTURING THE SAME

(75) Inventors: Naoyuki Nakagawa, Tokyo (JP); Shinya Sakurada, Tokyo (JP); Yasutaka Nishida, Kanagawa (JP); Satoshi Itoh, Ibaraki (JP); Michihiko Inaba, Kanagawa (JP)

(73) Assignee: KABUSHIKI KAISHA TOSHIBA, Tokyo (JP)

(21) Appl. No.: 13/422,129

(22) Filed: Mar. 16, 2012

Related U.S. Application Data
(63) Continuation-in-part of application No. PCT/JP2011/055024, filed on Mar. 4, 2011.

(30) Foreign Application Priority Data
Mar. 5, 2010 (JP) 2010-049899

(51) Int. Cl. H01L 31/0264; H01L 31/0296; H01L 31/18; H01L 31/0272

(52) U.S. Cl. 136/260; 136/264; 136/262; 136/265; 438/98; 257/E31.124

(57) ABSTRACT

A compound thin film solar cell of an embodiment includes: as a light-absorbing layer a semiconductor thin film which contains Cu, an element A (A is at least one element selected from a group consisting of Al, In and Ga) and Te, and has a chalcopyrite crystal structure, wherein a buffer layer that forms an interface with the light-absorbing layer is a compound which contains at least one element selected from Cd, Zn and a group consisting of In and Ga and at least one element selected from a group consisting of S, Se and Te, and has any crystal structure of a sphalerite structure, a wurtzite structure and a defect spinel structure, and a lattice constant “a” of the buffer layer with the sphalerite structure or a lattice constant “a” of the buffer layer at the time of converting the wurtzite structure or the defect spinel structure to the sphalerite structure is not smaller than 0.59 nm and not larger than 0.62 nm.

### CROSS-REFERENCE TO RELATED APPLICATION

This application is a continuation-in-part (CIP) application based upon International Application PCT/JP2011/055024, the International Filing Date of which is MARCH 4, 2011 the entire contents of which are incorporated herein by reference.

### FIELD

Embodiments described herein relate generally to a compound thin film solar cell and a method for manufacturing the same.

### BACKGROUND

In a compound thin film solar cell, group-II-VI CdTe, group-II and group-VI, or group-I-III-VI₂ CuInSe₂ and Cu(In, Ga)Se₂ (as it called CIGS), group-I, group-III and groue-VI₂ with a chalcopyrite structure are widely used as a light-absorbing layer. Selecting a constitutional element of a chalcopyrite compound semiconductor can lead to large modulation of a band gap (Eg).

For example, as one of techniques for increased efficiency in a CIGS solar cell used CIGS as a light-absorbing layer, there is a technique of changing a composition ratio of In and Ga in the light-absorbing layer to control a band gap so as to form a distribution in the band gap. However, in the case of changing the composition ratio of In, Ga and the like in the light-absorbing layer to control the band gap, it is essential to strictly control supply of a constitutional element at the time of film formation by vacuum deposition. Further, stacking a plurality of compound semiconductor layers with different constitutional elements and composition ratios of the light-absorbing layers can constitute a solar cell including light-absorbing layers with different band gaps, which can widen a band of wavelength sensitivity.

A compound thin film solar cell with Cu(In₁₋ₓGaₓ)(Se_{1-y}S_{y})₂ used for the light-absorbing layer contains In and Ga as constitutional elements. In and Ga are rear metals, and are likely to be difficult to stably supply for a reason of small amounts of resource deposits thereof, a reason of economical difficulties in finding minable ores of high grade, or some other reason. Further, refining ores is not easy for a reason of the refining requiring highly advanced technique and large energy, or some other reason, which has caused its price to be extremely high.

A highly efficient CIGS, Cu(In₁₋ₓGaₓ)Se₂, solar cell is obtained by means of a thin film of a p-type semiconductor with CIGS having a composition of group III slightly in excess with respect to a stoichiometric proportion. As a production method therefor, multiple vapor deposition, especially three-stage method, is employed. In the three-stage method, In, Ga and Se are deposited to form a (In, Ga)₂Se₃ film on a first layer, only Cu and Se are then supplied to make the composition of the entire film a composition with excess Cu, and finally, In, Ga and Se fluxes are supplied again, to make a final composition of the film a composition with excess (In, Ga). A vapor evaporation method is capable of precisely controlling a chemical composition, to produce a highly efficient CIGS solar cell, but has difficulties in increasing an area under process restrictions.

### BRIEF DESCRIPTION OF THE DRAWINGS

FIG. 1 is a schematic view of a compound thin film solar cell according to a first embodiment.

FIG. 2 is a graph showing a band gap and a lattice constant “a” of a light-absorbing layer in the first embodiment.

FIG. 3 is a graph showing a band gap of a buffer layer and a lattice constant “a” of the buffer layer with a sphalerite structure or a lattice constant “a” of the buffer layer at the time of converting a wurtzite structure to the sphalerite structure.

FIG. 4A is a TEM image according to a cross section of a Te compound semiconductor thin film solar cell, deposited on a back electrode by a sputtering method.

FIG. 4B is a TEM image according to a cross section of a Te compound semiconductor thin film solar cell, deposited on a back electrode by a sputtering method.

FIG. 5 is a schematic view of a compound thin film solar cell according to a second embodiment.

FIG. 6 is a result of a TEM-EDX analysis on a cross section of a compound thin film solar cell in a second embodiment.

FIG. 7 is a schematic view of a compound thin film solar cell according to a third embodiment.

FIG. 8 is a schematic view of another compound thin film solar cell according to the third embodiment.

### DETAILED DESCRIPTION

A compound thin film solar cell of an embodiment includes: as a light-absorbing layer a semiconductor thin film which contains Cu, an element A (A is at least one element selected from a group consisting of Al, In and Ga) and Te, and has a chalcopyrite crystal structure, wherein a buffer layer that forms an interface with the light-absorbing layer is a compound which contains at least one element selected from Cd, Zn and a group consisting of In and Ga and at least one element selected from a group consisting of S, Se and Te, and has any crystal structure of a sphalerite structure, a wurtzite structure and a defect spinel structure, and a lattice constant “a” of the buffer layer with the sphalerite structure or a lattice constant “a” of the buffer layer at the time of converting the wurtzite structure or the defect spinel structure to the sphalerite structure is not smaller than 0.59 nm and not larger than 0.62 nm.

Embodiments of the invention will be described below with reference to the drawings.

### First Embodiment

In a CIGS compound thin film solar cell having a chalcopyrite structure (group I-group III-group VI), a band offset is formed on a pn-junction interface by use of CdS as a buffer layer, so as to reduce recombination of carriers and obtain high conversion efficiency. A large number of CIGS solar cells have such characteristics that S and Se are used as group VI elements of a light-absorbing layer, and lattice constants of the light-absorbing layer and a buffer layer are close to each other.

On the other hand, there has hardly been consideration of a light-absorbing layer (Te light-absorbing layer) having a chalcopyrite structure using Te in place of S and Se for the group VI element. A lattice constant of the Te light-absorbing layer has a large value as compared with those using S and Se for the group VI element. Hence it is not known whether selecting a material suitable for the Te light-absorbing layer as a buffer layer is necessary and what material is preferred.

Thus, attention was paid upon the crystal structures and the lattice constants of Te light-absorbing layer and the buffer layer, to invent a compound thin film solar cell having a buffer layer which has any crystal structure of a sphalerite structure, a wurtzite structure and a defect spinel structure, and has a small difference in lattice constant between the Te light-absorbing layer and buffer layer.

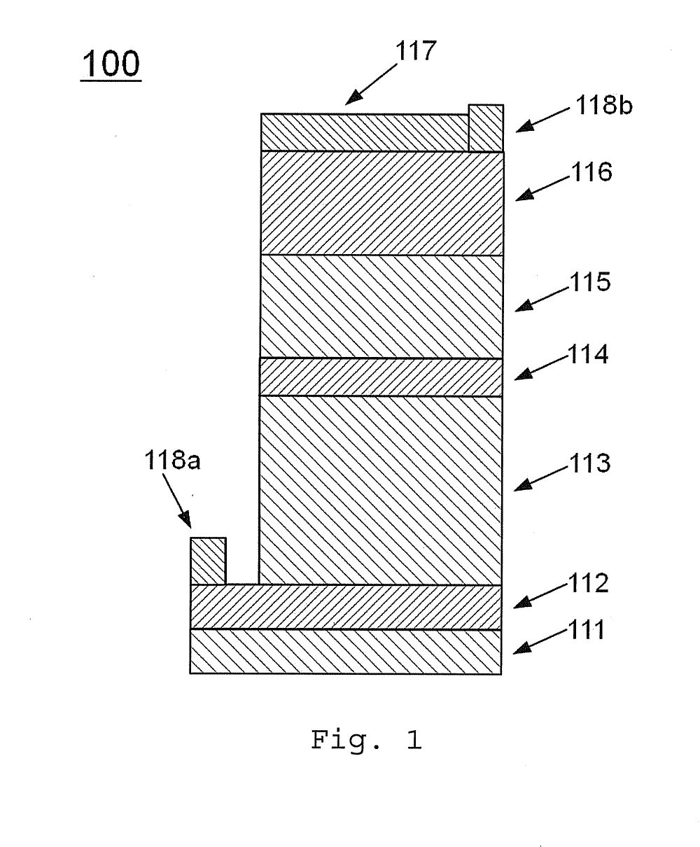

First, FIG. 1 shows a sectional schematic view of an example of a compound thin film solar cell 100 according to a first embodiment. The compound thin film solar cell 100 at least includes a substrate 111, a back electrode 112 provided on the substrate 111, a light-absorbing layer 113 provided on the back electrode 112, a buffer layer 114 provided on the light-absorbing layer 113, a semi-insulating layer 115 provided on the buffer layer 114, a transparent electrode layer 116 provided on the semi-insulating layer, an anti-reflective film 117 provided on a transparent electrode layer 116, a lead-out electrode 118a provided on the back electrode 112, and a lead-out electrode 118b provided on the transparent electrode layer 116.

For the substrate 111, soda-lime glass is desirably used, and a metal plate made of stainless, Ti or Cr or a resin such as polyimide can also be used.

For the back electrode 112, a metal film of Mo, W or the like can be used. Among them, a Mo film is desirably used.

For the light-absorbing layer used is a semiconductor thin film which contains Cu, an element A (A is at least one element selected from a group consisting of Al, In and Ga) and Te, and has the chalcopyrite crystal structure. A semiconductor thin film with part of Te replaced with O may also be used.

For the buffer layer 114 used is a compound to form a pn-junction interface with the light-absorbing layer 113 as a p-type. Specifically, a compound which contains at least one element selected from Cd, Zn and a group consisting of In and Ga and at least one element selected from a group consisting of S, Se and Te, and has any crystal structure of the sphalerite structure, the wurtzite structure and the defect spinel structure can be used, and in consideration of lattice matching with the light-absorbing layer 113, a lattice constant “a” of the buffer layer with the sphalerite structure or a lattice constant “a” of the buffer layer converting the wurtzite structure or the defect spinel structure to the sphalerite structure is preferably not smaller than 0.59 nm and not larger than 0.62 nm.

For formation of an n-type, a trace amount of at least one element of B, Al, Ga, In and Cl can be added as an additive. With the added amount being a trace, it has no influence upon the lattice constant.

The pn-junction interface may be a joint between the light-absorbing layer 113 and the buffer layer 114, or part of Cd and Zn may diffuse to the light-absorbing layer 113 so as to form the pn-junction interface inside the light-absorbing layer 113.

For the semi-insulating layer 115, ZnO or the like which is considered to function as a n+(plus) type layer can be used.

The transparent electrode layer 116 is required to transmit sunlight and also have conductivity, and for example, ZnO:Al containing 2-wt % alumina (Al₂O₃) or ZnO:B obtained by using B from diborane as a dopant can be used.

In order to efficiently take in the sunlight, it is desirable to provide the anti-reflective film 117. For the anti-reflective film 117, for example, MgF₂ can be used.

For the lead-out electrode 118, for example, Al, Ag or Au can be used. Further, in order to improve adhesion with the transparent electrode layer 15, Al, Ag or Au can be deposited after the deposition of Ni or Cr.

The following method is cited as an example of a method for manufacturing the compound thin film solar cell 100 of FIG. 1.

A method for manufacturing a compound thin film solar cell according to the first embodiment includes the steps of: forming a back electrode on a substrate; forming a light-absorbing layer which includes a compound semiconductor thin film on the back electrode; forming a buffer layer on the light-absorbing layer; forming a semi-insulating layer on the buffer layer; forming a transparent electrode layer on the semi-insulating layer; forming lead-out electrodes on the back electrode and the transparent electrode layer; and forming an anti-reflective film on the transparent electrode layer.

It is to be noted that the following manufacturing method is an example, and may be changed as appropriate. Therefore, the sequence of the steps may be changed, or a plurality of steps may be combined. The step of heat-treating the light-absorbing layer formed by the sputtering method is preferably performed at the time of adjusting a band gap of the light-absorbing layer 113.

[Step of Forming Back Electrode on Substrate]

The back electrode 112 is formed on the substrate 111. Examples of the film deposition method include the sputtering method.

[Step of Forming Light-Absorbing Layer on Back Electrode]

After deposition of the back electrode 112, a compound semiconductor thin film to be the light-absorbing layer 113 is deposited. It should be noted that, since the light-absorbing layer 113 and the lead-out electrode 118a are deposited on the back electrode 112, the light-absorbing layer 113 is deposited on part of the top of the back electrode 112 at least except for an area where the lead-out electrode 118a is deposited. Examples of the film deposition method include vacuum processes such as the sputtering method and the vacuum evaporation method. In the sputtering method, every constitutional element of the light-absorbing layer is supplied from a sputter target. The target as a supply source may be one or a plurality of targets. In the formed thin film, a stoichiometric composition, occasionally a feed composition of a constitutional element made to have a group III element slightly in excess, is desirably adjusted in advance, and a deficient element may be supplied from another target.

[Step of Heat-Treating Light-Absorbing Layer]

After the film deposition, a film deposition chamber is vacuated and annealing is performed in an ultra-high vacuum atmosphere. The light-absorbing layer 113 immediately after the film deposition by sputtering is amorphous and has a very small grain size. Thereat, performing annealing at high temperature can crystallize the light-absorbing layer 113. An average grain size of the crystal differs depending upon an annealing temperature. The annealing temperature is, for example, not lower than 200° C. and not higher than 500° C.

For crystallization of the compound semiconductor thin film, other than annealing that is performed after the film deposition of the semiconductor thin film, the annealing may be performed during the film deposition. The heating treatment is performed by annealing, infrared rays or the like, and the heating device is not particularly restricted.

[Step of Forming Buffer Layer on Light-Absorbing Layer]

The buffer layer 114 is deposited on the obtained absorbing layer 113.

Examples of the method for forming the buffer layer 114 include the sputtering method, the vacuum evaporation method and a metal organic chemical vapor deposition (MOCVD) method as the vacuum processes, and a chemical bath deposition (CED) as a liquid-phase process.

[Step of Forming Semi-Insulating Layer on Buffer Layer]

The semi-insulating layer 115 is deposited on the obtained buffer layer 114.

Examples of the method for forming the semi-insulating layer 115 include the sputtering method, the vacuum evaporation method and the metal organic chemical vapor deposition (MOCVD) method as the vacuum processes.

[Step of Forming Transparent Electrode Layer on Semi-Insulating Layer]

Subsequently, the transparent electrode layer 116 is deposited on the semi-insulating layer 115.

Examples of the deposition method include the sputtering method and the vacuum evaporation method and the metal organic chemical vapor deposition (MOCVD) method as the vacuum processes.

[Step of Forming Lead-Out Electrodes on Back Electrode and Transparent Electrode Layer]

The lead-out electrode 118a is deposited on an area at least excluding an area where the light-absorbing layer 113 on the back electrode 112 is formed.

The lead-out electrode 118b is deposited on an area at least excluding an area where the anti-reflective film 117 on the transparent electrode layer 116 is formed.

Examples of the film deposition method include the sputtering method and the vacuum evaporation method.

The lead-out electrodes may be formed by one step or formed by steps as separate ones after arbitrary steps.

[Step of Forming Anti-Reflective Film on Transparent Electrode Layer]

Finally, the anti-reflective film 117 is deposited on an area at least excluding an area where the lead-out electrode 118b on the transparent electrode layer 116 is formed.

Examples of the film deposition method include the sputtering method and the vacuum evaporation method.

The compound thin film solar cell shown in the conceptual view of FIG. 1 is produced through the above steps.

In the case of producing a module for the compound thin film solar cell, a step of dividing the back electrode with a laser is put after the step of forming the back electrode on the substrate, and steps of dividing the specimen by mechanical scribing are respectively put after the step of forming the buffer layer on the light-absorbing layer and the step of forming the transparent electrode layer on the buffer layer, thereby to allow integration.

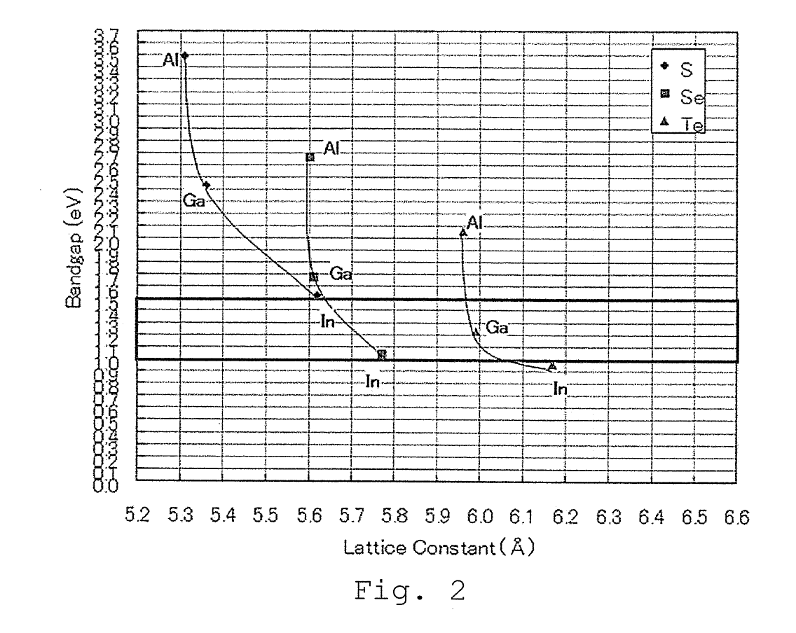

As a lattice constant “a” (nm) of the buffer layer 114 in the first embodiment, one having as small a mismatch as possible, or no mismatch, with a lattice constant “a” of the light-absorbing layer 113 is preferably used since it can result in production of a highly efficient solar cell. FIG. 2 shows a band gap and a value of a lattice constant “a” of each of S/Se/Te chalcopyrite light-absorbing layers (group I: Cu). With a lattice constant “a” of CdS being about 0.58 nm, a lattice mismatch between the CIGS thin film light-absorbing layer and CdS is about 4% at the maximum, and when a lattice mismatch of the Te light-absorbing layer is on the same level as the lattice mismatch between CIGS and CdS, an equivalent effect or a larger effect upon improvement in conversion efficiency can be expected. Thus, a specific lattice constant “a” (nm) of the buffer layer 114 according to the first embodiment is preferably not smaller than 0.59 and not larger than 0.62.

A compound, in which a lattice constant “a” of the sphalerite structure or a lattice constant “a” at the time of converting the wurtzite structure or the defect spinel structure to the sphalerite structure is not smaller than 0.59 nm and not larger than 0.62 nm and which is preferred as the buffer layer, is a compound which contains one or more elements selected from Cd, Zn and a group consisting of In and Ga and one or more elements selected from a group consisting of Te, Se and S, and has any crystal structure of the sphalerite structure, the wurtzite structure and the defect spinel structure. The compound, in which a lattice constant “a” of the sphalerite structure or a lattice constant “a” (nm) at the time of converting the wurtzite structure or the defect spinel structure to the sphalerite structure is not smaller than 0.59 nm and not larger than 0.62 nm and which has any crystal structure of the sphalerite structure, the wurtzite structure and the defect spinel structure may be formed by selecting as appropriate a preferred combination from CdTe, CdSe, CdS, ZnTe, ZnSe, ZnS, In₂Te₃, In₂Se₃, In₂S₃, Ga₂Te₃, Ga₂Se₃ and Ga₂S₃.

A description is given taking as an example the case of the lattice constant “a” (nm) at the time of converting the sphalerite structure. The wurtzite structure is hexagonal, and when its lattice constant is referred to as “a′” (nm), the lattice constant “a” (nm) at the time of converting the sphalerite structure can be given by the following formula.

a (nm)=√2×a′ (nm)

Similarly, also in the case of the defect spinel structure, the lattice constant “a” (nm) at the time of converting the sphalerite structure can be decided.

For formation of an n-type, a trace amount of at least one element of B, Al, Ga, In and Cl can be added as an additive. With the added amount being a trace, it has no influence upon the lattice constant.

In addition, a band gap of the light-absorbing layer 113 of Cu(Al_{1-a-b}InₐGa_{b})Te₂, being not smaller than 1.0 and not larger than 1.5, is preferred since the conversion efficiency is high. a and b in Cu(Al_{1-a-b}InₐGa_{b})Te₂ whose band gap is not smaller than 1.0 and not larger than 1.5 satisfy the following formula.

CuAlTe₂:2.25 eV, CuInTe₂:1.23 eV, CuGaTe₂:0.96 eV Eg (eV)=2.25(1−a−b)+1.23a+0.96b, 1.0≦Eg (eV)≦1.5 0≦a≦1, 0≦b≦1

Further, the light-absorbing layer 113 can be annealed so as to adjust its grain size and band gap. Hence in the case of heat-treating the light-absorbing layer 113, a and b in Cu(Al_{1-a-b}InₐGa_{b})Te₂ are not restricted to the above conditions.

Further, Cu(Al_{1-a-b}InₐGa_{b})(Te_{1-α}O_{α})₂ can also be used as the light-absorbing layer 113.

Part of Te can be replaced with oxygen so as to form an intermediate band inside the gap. From a calculation result, when an amount a replaced with oxygen in Cu(Al_{1-a-b}InₐGa_{b})(Te_{1-α}O_{α})₂ is not smaller than 0.001 and not larger than 0.0625, the intermediate band is formed, and high conversion efficiency is desired. The smaller the amount replaced with oxygen, the steeper a density of states of the intermediate band becomes. Preferable values may be selected as appropriated as a ratio of Al, In and Ga in consideration of formation of the mid level and heating conditions for the heating treatment. As a mother phase for forming the intermediate band in the light-absorbing layer, a wide-gap semiconductor is effectively used, whereby the sunlight with the different wavelength can be efficiently taken in, so as to produce a compound thin film solar cell with high conversion efficiency. Accordingly, CuAlTe₂ as the wide gap semiconductor is more preferably used for the mother phase, and one obtained by replacing part or all of Al with In or Ga may also be used.

The compound thin film semiconductor of the light-absorbing layer 113 is heat-treated during or after the film deposition, so as to adjust its grain size (band gap). The higher the heating temperature, the more the grain size of the compound thin film semiconductor grows.

It is preferable that, when the average grain size of the compound semiconductor thin film is adjusted to not smaller than 1 nm and not larger than 100 nm, the band gap become one suitable for absorption of the sunlight. Previously using a compound semiconductor with a wide gap can control the band gap to one suitable for absorption of the sunlight in heating treatment at relatively low temperature.

Further, since the grain size is controlled by heating treatment after the film deposition, in the range of the average grain size being below 10 nm, the crystallinity is low and a suitable band gap may not be formed, and hence the average grain size of the compound semiconductor thin film is preferably not smaller than 10 nm and not larger than 100 nm.

As for the heating treatment on the light-absorbing layer 113, annealing in an ultra-high vacuum atmosphere is preferred. The annealing temperature is preferably a substrate temperature of not lower than 200° C. and not higher than 500° C. When the annealing temperature is in this range, the grain size preferably becomes such that the band gap becomes a value suitable for the light-absorbing layer 113 of the solar cell.

Furthermore, since the crystal growth proceeds at an initial stage of annealing, and gradually reaches a steady state, the time for annealing is preferably not shorter than 10 minutes and not longer than 120 minutes.

Further, forming the band offset at the pn-junction interface can reduce recombination of carriers, so as to improve conversion efficiency, which is preferred. From the viewpoint of improvement in conversion efficiency, the band offset is preferably not larger than 0.4 eV, more preferably not smaller than 0.1 eV and not larger than 0.4 eV, and further preferably not smaller than 0.1 eV and not larger than 0.35 eV.

Accordingly, the band gap of the buffer layer is preferably larger than 2.3 eV and not larger than 2.7 eV.

A compound, which has a band gap of larger than 2.3 eV and not larger than 2.7 eV and has any crystal structure of the sphalerite structure, the wurtzite structure and the defect spinel structure, may be formed by selecting as appropriate a preferred combination from CdTe, CdSe, CdS, ZnTe, ZnSe, ZnS, In₂Te₃, In₂Se₃, In₂S₃, Ga₂Te₃, Ga₂Se₃ and Ga₂S₃. For formation of an n-type, a trace amount of at least one element of B, Al, Ga, In and Cl can be added as an additive.

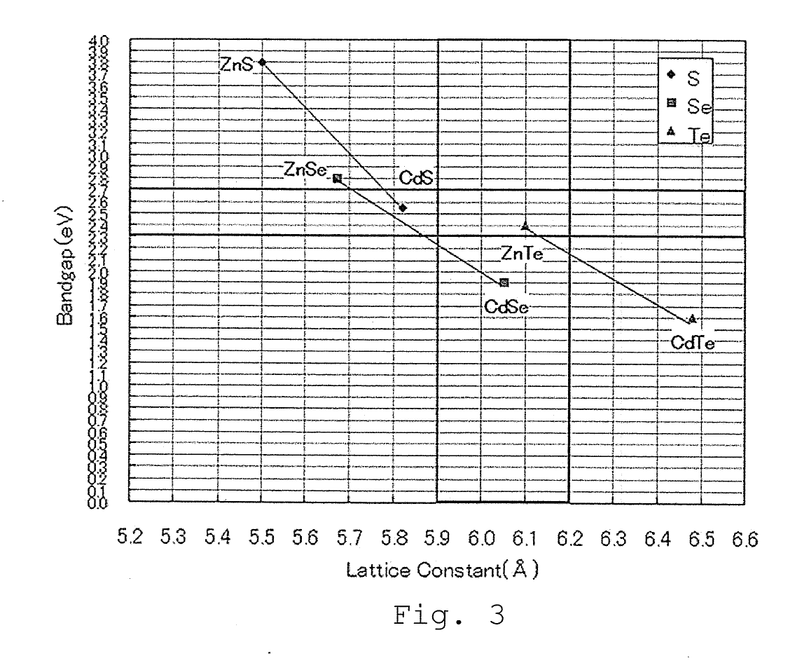

FIG. 3 shows a relation between a band gap and a lattice constant “a” (nm) of each of CdTe, CdSe, CdS, ZnTe, ZnSe and ZnS in the sphalerite structure or at the time of converting the wurtzite structure to the sphalerite structure. In FIG. 3, a range where the lattice constant “a” (nm) satisfies not smaller than 0.59 and not larger than 0.62 and a range where the band gap is larger than 2.3 eV and not larger than 2.7 eV are respectively enclosed by bold lines. A range where both the lattice constant “a” (nm) and the band gap are favorable ones in the first embodiment is an overlapped range enclosed by the bold line.

For example, as a component to be a favorable buffer layer in the first embodiment in combination of ZnTe, ZnSe and ZnS, there can be cited a compound of Zn(TeₓS₁₋ₓ) where x is larger than 0.8 and not larger than 1, or a compound of Zn(Te_{y}Se_{1-y}) where y is larger than 0.55 and not larger than 1.

Further, in the case of using Cd for the buffer layer, Cu of the light-absorbing layer is apt to diffuse to the buffer layer due to mutual diffusion. Therefore, since the use of the buffer layer containing Cd for the CIGS solar cell causes generation of a buffer layer which contains Cu due to mutual diffusion and is thus not pure, it is necessary to make the buffer layer have a large thickness in order to obtain a pure buffer layer with a constant thickness. On the other hand, in the case of using Zn for the buffer layer, since mutual diffusion of Cu occurs in a smaller degree than as compared with Cd, the thickness of the buffer layer for obtaining a pure buffer layer with a constant thickness can be made small as compared with the buffer layer in the case of using Cd.

Further, from the viewpoint of an environmental load, a compound thin film solar cell not using Cd and Se is preferably applied.

Moreover, in the case of the lattice constant “a” (nm) of the buffer layer being larger than the lattice constant “a” (nm) of the light-absorbing layer, a lattice constant of a Cu(Al, In, Ga)Te₂ light-absorbing layer increases and the lattice constant of the buffer layer decreases due to mutual diffusion of Cu and Zn, whereby, even when mismatching has originally occurred in the lattice constant “a” (nm), the mismatching can be almost or completely turned to lattice matching due to mutual diffusion.

In addition, since this mutual diffusion occurs through heat or the like at the time of depositing the buffer layer 114, a particular process for mutual diffusion is not required.

A composition distribution of the buffer layer at a direction of thickness of the buffer layer including the interface to the mutual diffusion is measured by cutting out a portion the thin film solar cell by using focused ion beam and making a line analysis cross-sectional cut by the Energy Dispersive X-ray (EDX) measurement.

Further, the lattice constant “a” of the buffer layer is calculating by identifying peak-position from X-ray Diffraction (XRD) measurement. Depending on the crystallinity of the buffer layer, even if the buffer layer thickness is thin, the lattice constant of the buffer layer whose thickness is 20 nm or more is calculated from X-ray diffraction measurement. For greater peak intensity of XRD, eliminating transparent electrode layer, etc. over the buffer layer is preferred. In case of obtained peak intensity being low, synchrotron radiation XRD is preferred.

### Second Embodiment

When the CIGS thin film as the light-absorbing layer of the compound semiconductor solar cell is formed on the Mo back electrode by the vapor evaporation method, an interfacial interlayer of MoSe₂ is formed on the GIGS thin film and the Mo back electrode. A c-axis of the interfacial interlayer becomes parallel or vertical to the surface of the Mo back electrode in accordance with a flux amount or the sequence of the deposition process of Cu, In, Ga and Se that are vapor deposited. Since the interfacial interlayer with a crystal surface being parallel or vertical to the surface of the Mo back electrode has a characteristic of being apt to peel or difficult to prevent from progression of peeling, the durability of the solar cell may be affected, and the conversion efficiency may also deteriorate associated with peeling. However, the interlayer formed between the CIGS light-absorbing layer and the Mo back electrode is known as bringing about ohmic contact.

Thus, attention was focused upon the interlayer formed between the light-absorbing layer and the back electrode, to invent a compound thin film solar cell, resistant to peeling and having an amorphous or polycrystalline interfacial interlayer which prevents deterioration in conversion efficiency of the solar cell.

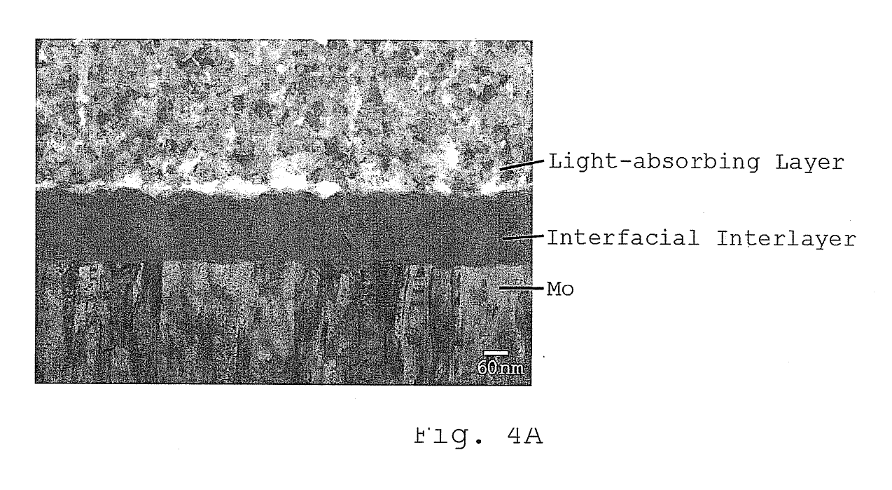

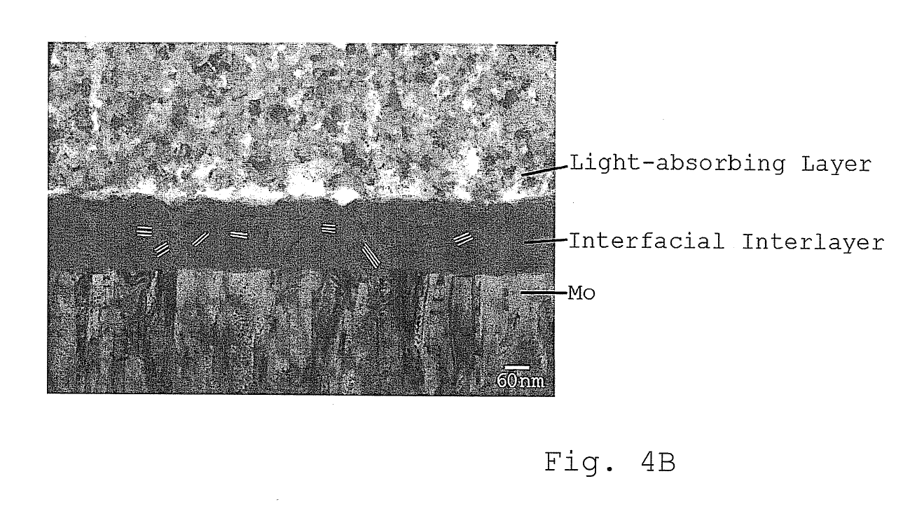

The interfacial interlayer of the second embodiment is a compound (MoTe₂) made up of Mo derived from the Mo back electrode and Te derived from the light-absorbing layer. A preferable back electrode and a preferable light-absorbing layer are ones formed by sputtering. As shown in FIG. 4, the MoTe₂ interlayer has been formed on the interface between the back electrode and the light-absorbing layer, and its crystal surface has been randomly oriented. It should be noted that FIGS. 4A and 4B are identical TEM images, and in FIG. 4B, the crystal surface is partially shown by white lines. The interfacial interlayer (MoTe2) is preferably amorphous or polycrystalline in order to improve peeling resistance. When the amorphous or polycrystalline interfacial interlayer is formed, a large number of grain boundaries are formed, and these larger number of grain boundaries suppress peeling of the layer.

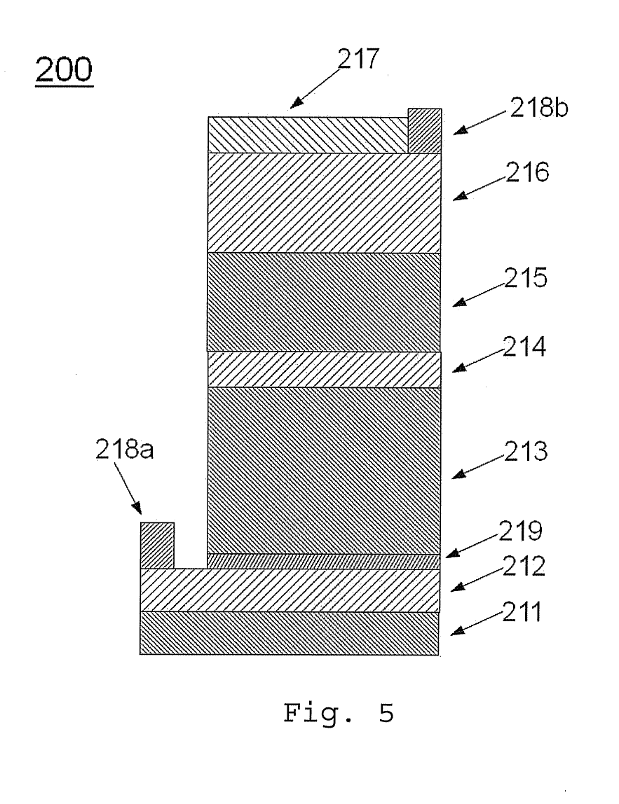

First, FIG. 5 shows a sectional schematic view of an example of a compound thin film solar cell 200 according to a second embodiment. The compound thin film solar cell 200 at least includes a substrate 211, a back electrode 212 provided on the substrate 211, a light-absorbing layer 213, provided on the back electrode 212, a buffer layer 214 provided on the light-absorbing layer 213, a semi-insulating layer 215 provided on the buffer layer 214, a transparent electrode layer 216 provided on the semi-insulating layer, an anti-reflective film 217 provided on a transparent electrode layer 216, a lead-out electrode 218a provided on the back electrode 212, and a lead-out electrode 218b provided on the transparent electrode layer 216, and an interfacial interlayer 219 between the back electrode 212 and the light-absorbing layer 213.

For the substrate 211, soda-lime glass is desirably used, and a metal plate made of stainless, Ti or Cr or a resin such as polyimide can also be used.

For the back electrode 212, a metal film made of Mo, W or the like can be used. Among them, a Mo film is desirably used.

For the light-absorbing layer 213 used is a compound semiconductor thin film which contains Cu, an element A (A is at least one element selected from a group consisting of Al, In and Ga) and Te, and has the chalcopyrite crystal structure. One with part of Te replaced with O may also be used.

For the buffer layer 214 used is a compound to form a pn-junction interface with the light-absorbing layer 213 as a p-type. Specifically, a compound is preferably used which contains at least one element selected from Cd, Zn and a group consisting of In and Ga and at least one element selected from a group consisting of S, Se and Te, and has any crystal structure of the sphalerite structure, the wurtzite structure and the defect spinel structure. For formation of an n-type, a trace amount of at least one element of B, Al, Ga, In and Ca can be added as an additive.

The pn-junction interface may be formed between the light-absorbing layer 213 and the buffer layer 214, or part of Cd and Zn may diffuse to the light-absorbing layer 213 so as to form the pn-junction interface inside the light-absorbing layer 213.

For the semi-insulating layer 215, ZnO or the like which is considered to function as a n+(plus) type layer can be used.

The transparent electrode layer 216 is required to transmit sunlight and also have conductivity, and for example, ZnO:Al containing 2-wt % alumina (Al₂O₃) or ZnO:B obtained by using B from diborane as a dopant can be used.

In order to efficiently take in the sunlight, it is desirable to provide the anti-reflective film 217. For the anti-reflective film 217, for example, MgF₂ can be used.

For the lead-out electrode 218, for example, Al, Ag or Au can be used. Further, in order to improve adhesion with the transparent electrode layer 15, Al, Ag or Au can be deposited after the deposition of Ni or Cr.

The interfacial interlayer 219 is a compound containing Te which is a constitutional element of the back electrode 212 and the light-absorbing layer 213. For example, when the back electrode is Mo, MoTe₂ is formed as the interfacial interlayer.

The following method is cited as an example of a method for manufacturing the compound thin film solar cell 200 of FIG. 5.

A method for manufacturing a compound thin film solar cell according to the second embodiment includes the steps of: forming a back electrode on a substrate; forming a light-absorbing layer which includes a compound semiconductor thin film on the back electrode; forming a buffer layer on the light-absorbing layer; forming a semi-insulating layer on the buffer layer; forming a transparent electrode layer on the semi-insulating layer; forming lead-out electrodes on the back electrode and the transparent electrode layer; forming an anti-reflective film on the transparent electrode layer; and forming an interfacial interlayer at an interface between the back electrode and the light-absorbing layer.

It is to be noted that the following manufacturing method is an example, and may be changed as appropriate. Therefore, the sequence of the steps may be changed, or a plurality of steps may be combined.

[Step of Forming Back Electrode on Substrate]

The back electrode 212 is deposited on the substrate 211. Examples of the film deposition method include the sputtering method.

[Step of Forming Light-Absorbing Layer on Back Electrode]

After deposition of the back electrode 212, a compound semiconductor thin film to be the light-absorbing layer 213 is deposited. It should be noted that, since the light absorbing layer 213 and the lead-out electrode 218a are deposited on the back electrode 212, the light-absorbing layer 213 is deposited on part of the top of the back electrode 212 at least except for an area where the lead-out electrode 218a is deposited. Examples of the film deposition method include vacuum processes such as the sputtering method and the vacuum evaporation method. Among them, the sputtering method in which the amorphous light-absorbing layer 213 is formed is preferred from the viewpoint of peeling resistance characteristic of the light-absorbing layer 213. In the sputtering method, every constitutional element of the light-absorbing layer 213 is supplied from a sputter target. The target as a supply source may be one or a plurality of targets. In the formed thin film, a stoichiometric composition, occasionally a feed composition of a constitutional element made to have a group III element slightly in excess, is desirably adjusted in advance, and a deficient element may be supplied from another target.

In addition, it is effective to control a deposition speed and a growth temperature for promoting the grain growth of the light-absorbing layer 213.

[Step of Heat-Treating Light-Absorbing Layer]

After the film deposition, the film deposition chamber is evacuated and annealing is performed in an ultra-high vacuum atmosphere. The light-absorbing layer 213 immediately after the film deposition by sputtering is amorphous and has a very small grain size. Thus, performing annealing at high temperature can crystallize the light-absorbing layer 213. An average grain size of the crystal differs depending upon an annealing temperature. Further, the interfacial interlayer is formed on the interface between the back electrode 212 and the 213 by annealing. The annealing temperature is, for example, not lower than 200° C. and not higher than 500° C. After the annealing, the layer is preferably cooled for example at a cooling ratio of not higher than 1° C./min down to room temperature.

For formation of the interfacial interlayer 219 and crystallization of the compound semiconductor thin film, other than annealing that is performed after the film deposition of the semiconductor thin film, the annealing may be performed during the film deposition. The heating treatment is performed by annealing, infrared rays or the like, and the heating device is not particularly restricted.

[Step of Forming Buffer Layer on Light-Absorbing Layer]

The buffer layer 214 is deposited on the obtained absorbing layer 213.

Examples of the method for forming the buffer layer 214 include the sputtering method, the vacuum evaporation method and the metal organic chemical vapor deposition (MOCVD) method as the vacuum processes and the chemical bath deposition (CBD) as the liquid-phase process.

[Step of Forming Semi-Insulating Layer on Buffer Layer]

The semi-insulating layer 215 is deposited on the obtained buffer layer 214.

Examples of the method for forming the semi-insulating layer 215 include the sputtering method, the vacuum evaporation method and the metal organic chemical vapor depoaition (MOCVD) method as the vacuum processes.

[Step of Forming Transparent Electrode Layer on Semi-Insulating Layer]

Subsequently, the transparent electrode layer 216 is deposited on the semi-insulating layer 215.

Examples of the deposition method include the sputtering method, the vacuum evaporation method and the metal organic chemical vapor deposition (MOCVD) method as the vacuum processes.

[Step of Forming Lead-Out Electrodes on Back Electrode and Transparent Electrode Layer]

The lead-out electrode 218a is deposited on an area at least excluding an area where the light-absorbing layer 213 on the back electrode 212 is formed.

The lead-out electrode 218b is deposited on an area at least excluding an area where the anti-reflective film 217 on the transparent electrode layer 216 is formed.

Examples of the film deposition method include the sputtering method and the vacuum evaporation method.

The lead-out electrode 218 may be formed by one step or formed by steps as separate ones after arbitrary steps.

[Step of Forming Anti-Reflective Film on Transparent Electrode Layer]

Finally, the anti-reflective film 217 is deposited on an area at least excluding an area where the lead-out electrode 218b on the transparent electrode layer 216 is formed.

Examples of the film deposition method include the sputtering method and the vacuum evaporation method.

The compound thin film solar cell shown in the conceptual view of FIG. 5 is produced through the above steps.

In the case of producing a module for the compound thin film solar cell, a step of dividing the back electrode 212 with a laser is put after the step of forming the back electrode 212 on the substrate 211, and steps of dividing the specimen by mechanical scribing are respectively put after the step of forming the buffer layer 214 on the light-absorbing layer 213 and the step of forming the transparent electrode layer 216 on the buffer layer, thereby to allow integration.

Hereinafter, a description is given to the light-absorbing layer 213 and the interfacial interlayer 219 in the second embodiment.

First, Cu(Al_{1-a-b}InₐGa_{b})Te₂ among the light-absorbing layers 213 used in the second embodiment is described.

A band gap of Cu(Al_{1-a-b}InₐGa_{b})Te₂, being not smaller than 1.0 and not larger than 1.5, is preferred since the conversion efficiency is high. Cu(Al_{1-a-b}InₐGa_{b})Te₂ with a band gap (eV) of not smaller than 1.0 and not larger than 1.5 may be one obtained by selecting values of a and b and heating conditions for heating treatment.

Next, Cu(Al_{1-a-b}InₐGa_{b})(Te_{1-α}O_{α})₂ is described.

Part of Te can be replaced with oxygen so as to form an intermediate band inside the gap. From a calculation result, when an amount a replaced with oxygen in Cu(Al_{1-a-b}InₐGa_{b})(Te_{1-α}O_{α})₂ is not smaller than 0.001 and not larger than 0.2, the intermediate band is formed, and high conversion efficiency is desired. The smaller the amount replaced with oxygen, the steeper a density of states of the intermediate band becomes. Preferable values may be selected as appropriated as a ratio of Al, In and Ga in consideration of formation of the mid potential and heating conditions for the heating treatment. As a mother phase for forming the intermediate band in the light-absorbing layer, a wide gap semiconductor is effectively used, whereby the sunlight with the different wavelength can be efficiently taken in, so as to produce a compound thin film solar cell with high conversion efficiency. Accordingly, CuAlTe₂ as the wide gap semiconductor is more preferably used for the mother phase, and one obtained by replacing part or all of Al with In or Ga may also be used.

The compound thin film semiconductor of the light-absorbing layer 213 is heat-treated during or after the film deposition, to adjust its grain size (band gap) so as to form the interfacial interlayer 219. The higher the heating temperature, the more the grain size of the compound thin film semiconductor grows.

It is preferable that, when the average grain size of the compound semiconductor thin film is adjusted to not smaller than 1 nm and not larger than 100 nm, the band gap become one suitable for absorption of the sunlight. Previously using a compound semiconductor with a wide gap can control the band gap to one suitable for absorption of the sunlight in heating treatment at relatively low temperature.

Further, when the thickness of the interfacial interlayer 219 becomes excessively large, the back electrode becomes resistant to functioning as the back electrode. The interfacial interlayer 219 preferably has a thickness not larger than 1 μm from the viewpoint of the function of the back electrode 212. The thickness of the interfacial interlayer is adjustable by the heating treatment temperature and the heating time after the film deposition. With a higher heating temperature and longer heating time, the thickness of the interfacial interlayer becomes larger.

Moreover, the grain size of the compound thin film of the light-absorbing layer 213 is also changed by the heating treatment after the film deposition. In the range of the average grain size being below 10 nm, the crystallinity is low and a suitable band gap may not be formed, and hence the average grain size of the compound semiconductor thin film is preferably not smaller than 10 nm and not larger than 100 nm.

As for the heating treatment on the light-absorbing layer 213, annealing in an ultra-high vacuum atmosphere is preferred. The annealing temperature is preferably a substrate temperature of not lower than 200° C. and not higher than 500° C. When the annealing temperature is in this range, the grain size preferably becomes such that the band gap becomes a value suitable for the light-absorbing layer 213 of the solar cell.

Furthermore, since the crystal growth proceeds at an initial stage of annealing, and gradually reaches a steady state, the time for annealing is preferably not shorter than 10 minutes and not longer than 120 minutes.

Next, the interfacial interlayer 219 and its crystal orientation are described.

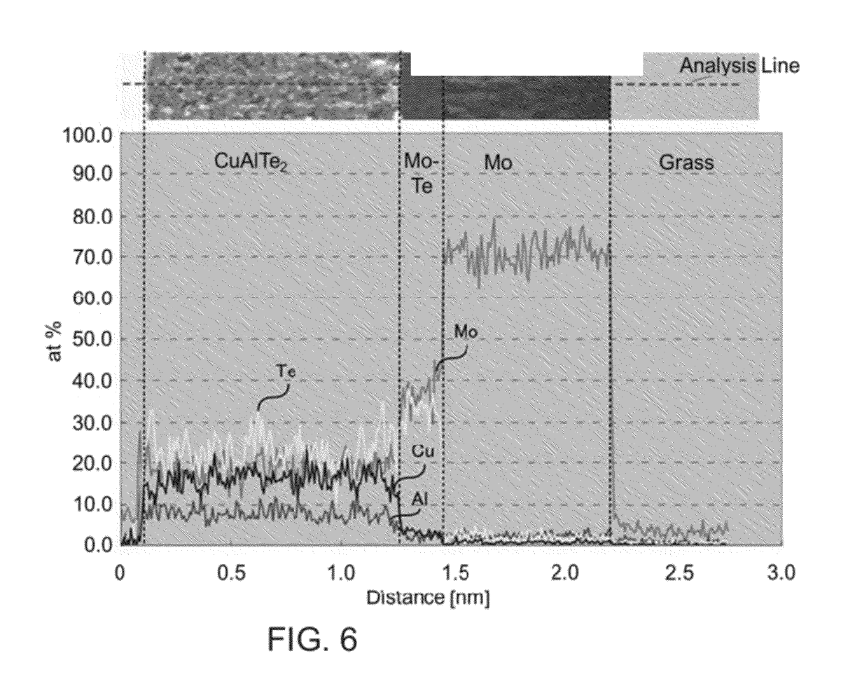

The interfacial interlayer 219 in the second embodiment preferably has a non-arrayed crystal lattice plane with respect to the surface of the back electrode 212, and specifically, the plane preferably has an amorphous or polycrystalline crystal structure so as to be excellent in peeling resistance. Such an interfacial interlayer 219 is formed by the foregoing heating treatment. FIG. 6 shows a result of Transmission Electron Microsope-Energy Dispersive X-ray spectroscopy (TEM-EDX) analysis on a cross section of the compound thin film solar cell according to the second embodiment. It should be noted that the compound thin film solar cell of FIG. 6 is produced on conditions shown in Example 4. Formation of the interfacial interlayer 219 and an element composition of the interfacial interlayer 219 can be seen from FIG. 6. As apparent from FIG. 6, the interfacial interlayer 219 is a layer including a compound made up of Mo derived from the back electrode 212 and Te derived from the light-absorbing layer 213.

The crystal structure of the interfacial interlayer 219 can be determined based upon a diffraction peak (peak intensity: I) of XRD. When an X-ray diffraction peak from the (hkl) surface is referred to as Iₕₖₗ, specifically, the crystal plane of the interfacial interlayer 219 is parallel to the surface of the back electrode 212 in a case where a peak of the X-ray diffraction peak (002) of the interfacial interlayer 219 is observed and a peak of (110) is not observed, and the crystal surface of the interfacial interlayer 219 is vertical to the surface of the back electrode 212 in a case where the peak of the crystal lattice plane (110) of the interfacial interlayer 219 is observed and the peak of (002) is not observed. Accordingly, when the peaks are present both on the crystal lattice planes (110) and (002) of the interfacial interlayer 219, the interfacial interlayer 219 is polycrystalline. It is to be noted that a broad peak is not included in peaks of the crystal lattice planes. Further, when the interfacial interlayer 219 is amorphous, the peaks become broad, and neither peaks of the crystal lattice planes (110) and (002) are observed.

From the above, the interfacial interlayer in the second embodiment becomes amorphous or polycrystalline when the peak intensity ratio of the crystal lattice planes (110) and (002) is in the range of 5>I₀₀₂/I₁₁₀>0.2. When the peak intensity ratio is I₀₀₂/I₁₁₀>5, the crystal plane of the interfacial interlayer 219 which is parallel to the surface of the back electrode 212 becomes large, and the peeling resistance is apt to deteriorate. Further, when the peak intensity ratio is I₀₀₂/I₁₁₀<0.2, the crystal plane of the interfacial interlayer 219 which is vertical to the surface of the back electrode 212 becomes large, and the peeling resistance is apt to deteriorate.

Although it is known that the chalcopyrite compound semiconductor thin film and soda-lime glass have coefficients of thermal expansion which are close to each other, at the time of stacking for producing the compound semiconductor thin film, forming the interfacial interlayer of the present invention can lead to further improvement in peeling resistance.

### Third Embodiment

Although a CIGS solar cell is known to be less likely to become the center of recombination of carriers among the compound thin film solar cells, it has been required to increase the grain size of the light-absorbing layer for further improvement in conversion efficiency. As for the vapor evaporation method, it is known that by means of a three-stage method, Cu and Se are supplied after deposition of (In, Ga)₂Se₃, to increase the grain size of the light-absorbing layer. However, the increase in grain size by means of the three-step method has a disadvantage that the number of steps is large and the method is thus difficult to apply to film deposition of a light-absorbing layer by the simple, sputtering method.

Thus, attention was focused upon the heating treatment being performed after deposition of the light-absorbing layer, a crystal growth nucleus or a crystal growth layer, which promote the grain growth of the light-absorbing layer on the back electrode before formation of the light-absorbing layer, thereby enabling an increase in grain size by a simple method in the sputtering method.

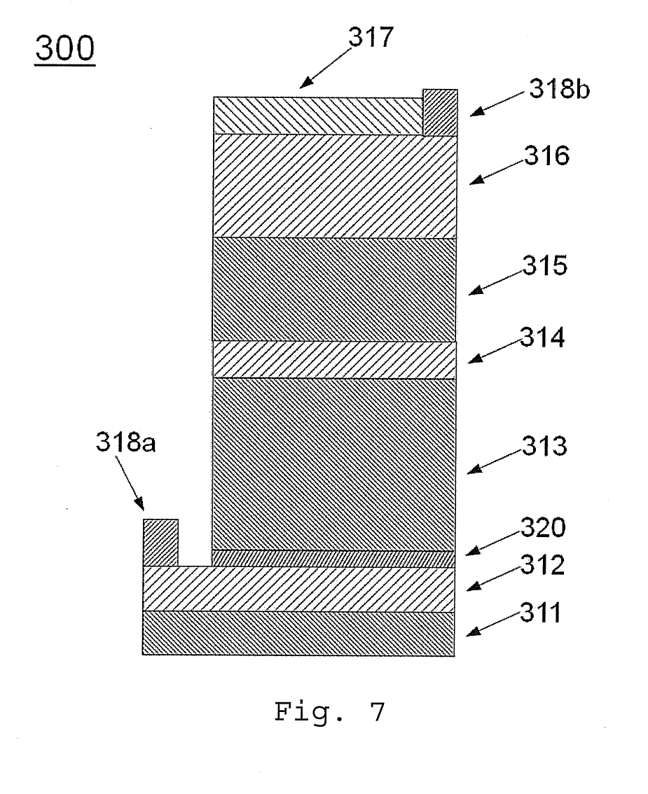

First, FIG. 7 shows a sectional schematic view of a compound thin film solar cell 300 according to a third embodiment. The compound thin film solar cell 300 at least includes a substrate 311, a back electrode 312 provided on the substrate 311, an interfacial crystal layer 320 provided on the back electrode 312, a light-absorbing layer 313 provided on the interfacial crystal layer 320, a buffer layer 314 provided on the light-absorbing layer 313, a semi-insulating layer 315 provided on the buffer layer 314, a transparent electrode layer 316 provided on the semi-insulating layer, an anti-reflective film 317 provided on a transparent electrode layer 316, a lead-out electrode 318a provided on the back electrode 312, and a lead-out electrode 318b provided on the transparent electrode layer 316.

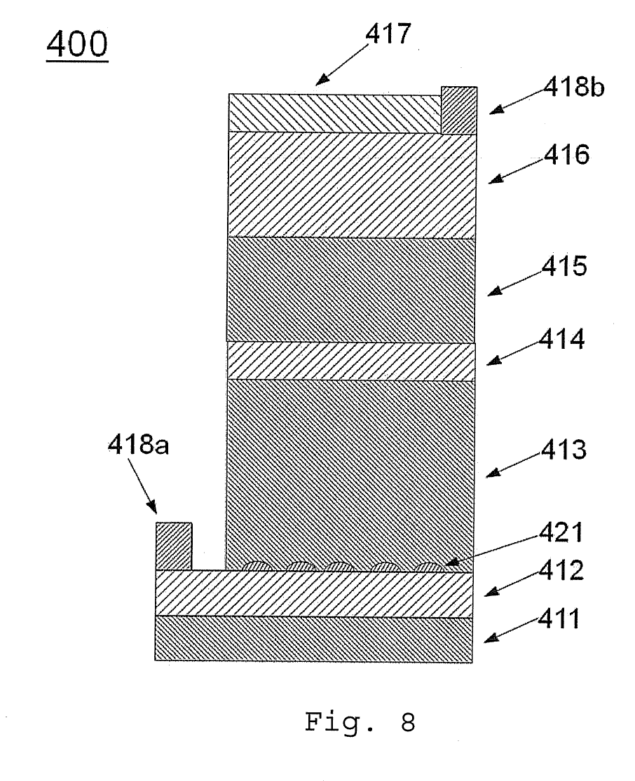

FIG. 8 shows a sectional schematic view of a compound thin film solar cell 400 according to the third embodiment. When compared with the compound thin film solar cell 300, the compound thin film solar cell 400 is the same as the compound thin film solar cell 300 except that an interfacial crystal nucleus 421 is provided in place of the interfacial crystal layer 320. The compound thin film solar cell 300 and the compound thin film solar cell 400 are the same except that which is formed, the interfacial crystal layer 320 or the interfacial crystal layer 421. Therefore, since descriptions of the compound thin film solar cell 400 other than a description of the interfacial crystal layer 421 overlap with those of the compound thin film solar cell 300, the overlapped descriptions are omitted.

For the substrate 311, soda-lime glass is desirably used, and a metal plate made of stainless, Ti or Cr or a resin such as polyimide can also be used.

For the back electrode 312, a metal film made of Mo, W or the like can be used. Among them, a Mo film is desirably used.

For the crystal growth layer 320 or the crystal growth nucleus 421 which is present on the back electrode 312 or 412 and the light-absorbing layer 313 or 413, a crystal phase of Cu_{c}A_{d}X_{1-c}-d is formed. A is at least one element selected from a group consisting of Al, In and Ga, X is at least one element selected from a group consisting of S, Se and Te.

For the light-absorbing layer 313 used is a compound semiconductor thin film which contains Cu, an element A (A is at least one element selected from a group consisting of Al, In and Ga) and an element X (X is at least one element selected from a group consisting of S. Se and Te), and has the chalcopyrite crystal structure. One with part of the element X replaced with O may also be used.

For the buffer layer 314 used is a compound to form a pn-junction interface with the light-absorbing layer 313 as a p-type. Specifically, a compound is preferably used which contains at least one element selected from Cd, Zn and a group consisting of In and Ga and at least one element selected from a group consisting of S, Se and Te, and has any crystal structure of the sphalerite structure, the wurtzite structure and the defect spinel structure. For formation of an n-type, a trace amount of at least one element of B, Al, Ga, In and Cl can be added as an additive.

The pn-junction interface may be formed between the light-absorbing layer 313 and the buffer layer 314, or part of Cd and Zn may diffuse to the light-absorbing layer 313 so as to form the pn-junction interface inside the light-absorbing layer 313.

For the semi-insulating layer 315, ZnO or the like which is considered to function as a n+(plus) type layer can be used.

The transparent electrode layer 316 is required to transmit sunlight and also have conductivity, and for example, ZnO:Al containing 2-wt % alumina (A₁₂O₃) or ZnO:B obtained by using B from diborane as a dopant can be used.

In order to efficiently take in the sunlight, it is desirable to provide the anti-reflective film 317. For the anti-reflective film 317, for example, MgF₂ can be used.

For the lead-out electrode 318, for example, Al, Ag or Au can be used. Further, in order to improve adhesion with the transparent electrode layer 15, Al, Ag or Au can be deposited after the deposition of Ni or Cr.

The following methods are cited as examples of method for manufacturing the compound thin film solar cells 300, 400 of FIGS. 7, 8.

A method for manufacturing a compound thin film solar cell according to the third embodiment includes the steps of: forming a back electrode on a substrate; forming a crystal growth layer on the back electrode; forming a light-absorbing layer which includes a compound semiconductor thin film on the crystal growth layer; forming a buffer layer on the light-absorbing layer; forming a semi-insulating layer on the buffer layer; forming a transparent electrode layer on the semi-insulating layer; forming lead-out electrodes on the back electrode and the transparent electrode layer; and forming an anti-reflective film on the transparent electrode layer.

It is to be noted that the following manufacturing method is an example, and may be changed as appropriate. Therefore, the sequence of the steps may be changed, or a plurality of steps may be combined.

[Step of Forming Back Electrode on Substrate]

The back electrode 312 is deposited on the substrate 311. Examples of the film deposition method include the sputtering method.

[Forming Crystal Growth Layer or Crystal Growth Nucleus on Back Electrode]

After deposition of the back electrode 312, the crystal growth layer 320 or the crystal growth nucleus 421 is deposited. The crystal growth layer 320 or the crystal growth nucleus 421 is deposited by the sputtering method. After deposition of the crystal growth layer 320 or the crystal growth nucleus 421, the film deposition chamber is evacuated and annealing is performed in an ultra-high vacuum atmosphere. When a surface coverage rate of the crystal growth layer 320 on the back electrode 312 is 100%, the crystal growth layer 320 is formed, and when it is less than 100%, atoms diffuse on the surface of the back electrode 312 to form the crystal growth nucleuses 421. The annealing temperature is, for example, not lower than 200° C. and not higher than 500° C. In the crystallization of the semiconductor thin film, the heating treatment is performed by annealing, infrared rays or the like, and the heating device is not particularly restricted.

[Step of Forming Light-Absorbing Layer on Back Electrode (Crystal Growth Layer, Crystal Growth Nucleus)]

A compound semiconductor thin film as the light-absorbing layer 313 is deposited. It is to be noted that since the light-absorbing layer 314 and the lead-out electrode 318a are deposited on the back electrode 312 where the crystal growth layer 320 or the crystal growth nucleus 421 is formed, the light-absorbing layer 313 is deposited on an area at least excluding an area where the lead-out electrode 318a is deposited. As the film deposition method, the simple, sputtering method is adopted. In the sputtering method, every constitutional element of the light-absorbing layer is supplied from a sputter target. The target as a supply source may be one or a plurality of targets. In the formed thin film, a stoichiometric composition, occasionally a feed composition of a constitutional element made to have a group III element slightly in excess, is desirably adjusted in advance, and a deficient element may be supplied from another target.

In addition, it is effective to control a deposition speed and a growth temperature for promoting the grain growth of the light-absorbing layer.

[Step of Heat-Treating Light-Absorbing Layer]

After the film deposition, a film deposition chamber is evacuated and annealing is performed in an ultra-high vacuum atmosphere. The light-absorbing layer 313 immediately after the film deposition by sputtering is amorphous and has a very small grain size. Thus, performing annealing at high temperature can crystallize the light-absorbing layer 313. In the third embodiment, with the crystal growth layer 320 or the crystal growth nucleus 421 formed on the back electrode 312 or 412, crystal growth is promoted by the heating treatment. An average grain size of the crystal differs depending upon an annealing temperature. The annealing temperature is, for example, not lower than 200° C. and not higher than 500° C.

In the crystallization of the semiconductor thin film, the heating treatment is performed by annealing, infrared rays or the like, and the heating device is not particularly restricted.

[Step of Forming Buffer Layer on Light-Absorbing Layer]

The buffer layer 314 is deposited on the obtained absorbing layer 313.

Examples of the method for forming the buffer layer 314 include the sputtering method, the vacuum evaporation method and the metal organic chemical vapor deposition (MOCVD) method as the vacuum processes, and the chemical bath deposition (CBD) as the liquid-phase process.

[Step of Forming Semi-Insulating Layer on Buffer Layer]

The semi-insulating layer 315 is deposited on the obtained buffer layer 314.

Examples of the method for forming the semi-insulating layer 315 include the sputtering method, the vacuum evaporation method and the metal organic chemical vapor deposition (MOCVD) method as the vacuum processes.

[Step of Forming Transparent Electrode Layer on Semi-Insulating Layer]

Subsequently, the transparent electrode layer 316 is deposited on the semi-insulating layer 315.

Examples of the formation method include the sputtering method, the vacuum evaporation method and the metal organic chemical vapor deposition (MOCVD) method as the vacuum processes.

[Step of Forming Lead-Out Electrodes on Back Electrode and Transparent Electrode Layer]

The lead-out electrode 318a is deposited on an area at least excluding an area where the light-absorbing layer 313 on the back electrode 312 is formed.

The lead-out electrode 318b is deposited on an area at least excluding an area where the anti-reflective film 317 on the transparent electrode layer 316 is formed.

Examples of the film deposition method include the sputtering method and the vacuum evaporation method.

The lead-out electrodes 318 may be formed by one step or formed by steps as separate ones after arbitrary steps.

[Step of Forming an Anti-Reflective Film on Transparent Electrode Layer]

Finally, the anti-reflective film 317 is deposited on an area at least excluding an area where the lead-out electrode 318b on the transparent electrode layer 316 is formed.

Examples of the film deposition method include the sputtering method and the vacuum evaporation method.

The compound thin film solar cell shown in the conceptual view of FIG. 7 or 8 is produced through the above steps.

In the case of producing a module for the compound thin film solar cell, a step of dividing the back electrode 312 with a laser is put after the step of forming the back electrode 312 on the substrate 311, and steps of dividing the specimen by mechanical scribing are respectively put after the step of forming the buffer layer 314 on the light-absorbing layer 313 and the step of forming the transparent electrode layer 315 on the buffer layer 314, thereby to allow integration.

Hereinafter, a description is given to the crystal growth layer 320 of the light-absorbing layer 313,413 and the light-absorbing nucleus 421 in the third embodiment.

First, a description is given to the crystal growth layer 320 and the crystal growth nucleus 421 for use in the third embodiment.

The crystal growth layer 320 and the crystal growth nucleus 421 are a layer/nucleus for making the light-absorbing layers 313, 413 grow, and crystal growth layer 320 and the crystal growth nucleus 421 contain a crystal phase of Cu_{c}A_{d}X_{1-c-d}. The element A of the crystal phase is preferably at least one element selected from a group consisting of Al, In and Ga used for the absorbing layers 313, 413 from the viewpoint of the crystal growth, and is more preferably the same one. The element X of the crystal phase is preferably at least one element selected from a group consisting of S, Se and Te used for the absorbing layers 313, 413 from the viewpoint of the crystal growth, and is more preferably the same one. c+d is preferably not smaller than 0.9 and not larger than 1. The nucleus that makes the light-absorbing layers 313, 413 grow is preferably mainly composed of the element A and the element X. Specifically, c is preferably not smaller than 0 and not larger than 0.1, and d is preferably not smaller than 0.1. As seen from the film deposition process by means of the multiple vapor deposition (three-stage method), the compound made up of A-X above is regarded as the crystal nucleus, whereby diffusion of Cu therein leads to promotion of an increase in grain size through a Cu—X liquid phase formed on the surface of the crystal nucleus.

The crystal growth layer preferably has a thickness not smaller than 1 nm and not larger than 10 nm from the viewpoint of the crystal growth. Further, it is preferable that an average grain size be not larger than 10 nm on the back electrode of the crystal growth nucleus 421, and the crystal growth nucleus 421 cover not less than 0.1% of an area on the back electrode where a light-absorbing layer 413 is deposited (area corresponding to the light-absorbing layer). A surface coverage ratio of the crystal growth nucleus 421 is the square of a total of crystal cross-section length obtained by sectional SEM observation. When the coverage ratio is the same, it is preferable that the crystal growth nucleus 421 be a fine grain, the number thereof be large, and be uniformly dispersed. When the grains of the crystal growth nucleuses 421 are finely and uniformly dispersed, the crystal growth is promoted from a large number of position on the surface of the back electrode, which is preferred.

Next, Cu(Al_{1-a-b}InₐGa_{b})Te₂ among the light-absorbing layers 313 used in the third embodiment is described.

A band gap of Cu(Al_{1-a-b}InₐGa_{b})Te₂, being not smaller than 1.0 and not larger than 1.5, is preferred since the conversion efficiency is high. Cu(Al_{1-a-b}InₐGa_{b})Te₂ with a band gap (eV) of not smaller than 1.0 and not larger than 1.5 may be one obtained by selecting values of a and b and heating conditions for heating treatment.

Next, Cu(Al_{1-a-b}InₐGa_{b})(Te_{1-α}O_{α})₂ is described.

Part of Te can be replaced with oxygen so as to form an intermediate band inside the gap. From a calculation result, when an amount a replaced with oxygen in Cu(Al_{1-a-b}InₐGa_{b})(Te_{1-α}O_{α}) is not smaller than 0.001 and not larger than 0.2, the intermediate band is formed, and high conversion efficiency is desired. The smaller the amount replaced with oxygen, the steeper a density of states of the intermediate band becomes. Preferable values may be selected as appropriated as a ratio of Al, In and Ga in consideration of formation of the mid potential and heating conditions for the heating treatment. As a mother phase for forming the intermediate band in the light-absorbing layer, a wide gap semiconductor is effectively used, whereby the sunlight with the different wavelength can be efficiently taken in, so as to produce a compound thin film solar cell with high conversion efficiency. Accordingly, CuAlTe₂ as the wide gap semiconductor is more preferably used for the mother phase, and one obtained by replacing part or all of Al with In or Ga may also be used.

The compound thin film semiconductor of the light-absorbing layer 313 is heat-treated during or after the film deposition, to adjust its grain size (band gap). The higher the heating temperature, the more the grain size of the compound thin film semiconductor grows. In the third embodiment, with the crystal growth layer 320 or the crystal growth nucleus 421 formed between the back electrodes 312, 421 and the light-absorbing layer 313, 413, the crystal growth is promoted.

In the third embodiment, the crystal growth is promoted at the time of performing the heating treatment on the light-absorbing layer, whereby it is possible to make the crystal grow equivalently in the process at low temperature as compared with the figuration without the crystal growth layer or the crystal growth nucleus.

Although it is known that the chalcopyrite compound semiconductor thin film and soda-lime glass have coefficients of thermal expansion which are close to each other, the crystal growth nucleus of the present invention can function also as an anchor before deposition of the light-absorbing layer, and initially depositing the crystal growth nucleus can improve the peeling resistance.

### EXAMPLES

### Example 1

A soda-lime glass substrate is used as the substrate, and a Mo thin film to be the back electrode is deposited by the sputtering method to have a thickness of the order of 700 nm. RF power of 200 W is performed in an Ar-gas atmosphere with Mo as a target, to perform sputtering.

After deposition of the Mo thin film to be the back electrode, a Cu(Al_{1-a-b}InₐGa_{b})Te₂ thin film to be the light-absorbing layer is deposited by the same RF sputtering to have a thickness of the degree of 2 μm. a and b are numerical values larger than 0 and smaller than 1. RF power of 200 W is performed in the Ar-gas atmosphere, to form the film. After the film deposition, a film deposition chamber is vacuated and annealing is performed in an ultra-high vacuum atmosphere at 500° C. The Cu(Al_{1-a-b}InₐGa_{b})Te₂ thin film immediately after the sputtering deposition is amorphous and has a very small grain size. Thus, annealing is performed at high temperature, to crystallize the Cu(Al_{1-a-b}InₐGa_{b})Te₂ thin film and increase the grain size thereof. The lattice constant “a” of the Cu(Al_{1-a-b}InₐGa_{b})Te₂ thin film at that time is in the range of 0.59 to 0.62 nm, and the band gap value is adjusted to from 1.0 to 1.5 eV as favorable band gap values for the light-absorbing layer.

A ZnTe thin film is deposited as the buffer layer on the obtained absorbing layer by the vacuum evaporation method, to have a thickness of the order of 50 nm. For the deposition of the ZnTe thin film, a solution-growth method or the sputtering method can be used other than the vacuum evaporation method. In the case of using the sputtering method, it is conducted with a low RF power in consideration of the plasma damage at the interface. Further, although the ZnTe thin film is a p-type semiconductor in normal film deposition, the film becomes n-type semiconductor with a defect of Zn compensated in the film deposition in a low-vacuum state. Moreover, for formation of an n-type, a trace amount of at least one element of B, Al, Ga, In and Cl can be added as an additive. A ZnO thin film is deposited as the semi-insulating layer on this buffer layer, and ZnO:Al containing 2-wt % alumina (Al₂O₃) to be the transparent electrode layer is deposited to have a thickness of the order of 1 μm. In addition to ZnO:Al, ZnO:B can also be used. As the lead-out electrode, Al, or NiCr and Au are deposited by the vapor evaporation method. Those are deposited so as to have a film thickness of the order of 300 nm. Finally, MgF₂ as the anti-reflective film is deposited by the sputtering method, to produce a compound thin film solar cell.

### Example 2

A compound thin film solar cell is manufactured in the same manner as in Example 1 except that Zn(TeₓS₁₋ₓ) to be the buffer layer is deposited by the vacuum evaporation method. For formation of the Zn(TeₓS₁₋ₓ) thin film, a solution-growth method or the sputtering method can be used other than the vacuum evaporation method. x is a numerical value larger than 0.8 and smaller than 1. Further, although the Zn(TeₓS₁₋ₓ) thin film is a p-type semiconductor in the above range of x, the film becomes n-type semiconductor with a defect of Zn compensated in film deposition in a low-vacuum state. Moreover, for formation of an n-type, a trace amount of at least one element of B, Al, Ga, In and Cl can be added as an additive.

Also in the case of using the Zn(TeₓS₁₋ₓ) layer as the buffer layer, there is good lattice matching with the Te chalcopyrite compound semiconductor thin film as the light-absorbing layer, to allow suppression of a lattice defect so as to obtain a highly efficient compound thin film solar cell.

### Example 3

A compound thin film solar cell is manufactured in the same manner as in Example 1 except that Zn(Te_{y}Se_{1-y}) to be the buffer layer is deposited by the vacuum evaporation method. For formation of the Zn(Te_{y}Se_{1-y}) thin film, a solution-growth method or the sputtering method can be used other than the vacuum evaporation method. y is a numerical value larger than 0.55 and smaller than 1. Further, although the Zn(Te_{y}Se_{1-y}) thin film is a p-type semiconductor in the above range of y, the film becomes n-type semiconductor with a defect of Zn compensated in film deposition in a low-vacuum state. Moreover, for formation of an n-type, a trace amount of at least one element of B, Al, Ga, In and Cl can be added as an additive.

Also in the case of using the Zn(Te_{y}Se_{1-y}) layer as the buffer layer, there is good lattice matching with the Te chalcopyrite compound semiconductor thin film as the light-absorbing layer, to allow suppression of a lattice defect so as to obtain a highly efficient compound thin film solar cell.

### Comparative Example 1

A compound thin film solar cell is manufactured in the same manner as in Example 1 except that CdS to be the buffer layer is deposited by the solution-growth method.

CdS used as the buffer layer has a large lattice mismatch with the Te chalcopyrite compound semiconductor thin film as the light-absorbing layer, and a large number of lattice defects occur on the pn-junction interface, thereby causing deterioration in conversion efficiency of the compound semiconductor thin film solar cell.

### Example 4

A soda-lime glass substrate is used as the substrate, and a Mo thin film to be the back electrode is deposited by the sputtering method to have a thickness of the order of 700 nm. RF power of 200 W is performed in an Ar-gas atmosphere with Mo as a target, to perform sputtering.

After deposition of the Mo thin film to be the back electrode, a Cu(Al_{1-a-b}InₐGa_{b})Te₂ thin film to be the light-absorbing layer is deposited by the same RF sputtering to have a thickness of the degree of 2 μm. a and b are numerical values larger than 0 and smaller than 1. RF power of 200 W is performed in the Ar-gas atmosphere, to form the film. After the film deposition, a film deposition chamber is evacuated and annealing is performed in an ultra-high vacuum atmosphere at 500° C. The Cu(Al_{1-a-b}InₐGa_{b})Te₂ thin film immediately after the sputtering deposition is amorphous and has a very small grain size, and a Mo—Te interlayer is not present at the interface between the light-absorbing layer and the back electrode. Thus, annealing is performed at high temperature, to crystallize the Cu(Al_{1-a-b}InₐGa_{b})Te₂ thin film and increase the grain size thereof, while forming the Mo—Te interlayer at the interface between the light-absorbing layer and the back electrode. Herein, the crystal in the Mo—Te interlayer is randomly oriented, thereby to improve the peeling resistance.

A ZnO thin film added with Mg was deposited as the buffer layer on the obtained absorbing layer, to have a thickness of the order of 50 nm. Although RF sputtering was used, it is preferably conducted with a power of 50 W in consideration of the plasma damage at the interface. Further, CdS can also be used for the buffer layer despite a large lattice mismatch with the Te chalcopyrite compound semiconductor film. A ZnO thin film is deposited as the semi-insulating layer on this buffer layer, and ZnO:Al containing 2-wt % alumina (Al₂O₃) to be the transparent electrode layer is deposited to have a thickness of the order of 1 μm. In addition to ZnO:Al, ZnO:B can also be used. As the lead-out electrode, Al, or NiCr and Au are deposited by the vapor evaporation method. Those are deposited so as to have a film thickness of the order of 300 nm. Finally, MgF₂ as the anti-reflective film is deposited by the sputtering method, to produce a compound thin film solar cell.

### Example 5

A compound thin film solar cell is manufactured in the same manner as in Example 4 except that Cu(Al_{1-a-b}InₐGa_{b})Se₂ to be the light-absorbing layer is deposited by RF sputtering.

a and b are numerical values larger than 0 and smaller than 1.

In the case of using Cu(Al_{1-a-b}InₐGa_{b})Se₂ as the light-absorbing layer, a randomly oriented Mo—Se interlayer is formed at the interface between the light-absorbing layer and the back electrode, thereby to improve the peeling resistance.

### Example 6

A compound thin film solar cell is manufactured in the same manner as in Example 4 except that Cu(Al_{1-a-b}InₐGa_{b})S₂ to be the light-absorbing layer is deposited by RF sputtering.

a and b are numerical values larger than 0 and smaller than 1.

In the case of using Cu(Al_{1-a-b}InₐGa_{b})S₂ as the light-absorbing layer, a randomly oriented Mo—Se interlayer is formed at the interface between the light-absorbing layer and the back electrode, thereby to improve the peeling resistance.

### Comparative Examples 2-4

A compound thin film solar cell is manufactured in the same manner as in Examples 4 to 6 except that the vacuum evaporation method is used for the deposition of the light-absorbing layer.

In the case of using the vacuum evaporation method, a crystal plane of the interlayer formed at the interface between the light-absorbing layer and the back electrode is parallel to the surface of the thin film, and peeling might occur at the interface.

In Examples 7 to 9 and in Comparative Example 5, the element A and the element X in a crystal layer which promotes the crystal growth of the light-absorbing layer at least include a corresponding element A or X which is contained in the light-absorbing layer.

### Example 7

A soda-lime glass substrate is used as the substrate, and a Mo thin film to be the back electrode is deposited by the sputtering method to have a thickness of the order of 700 nm. RF power of 200 W is performed in an Ar-gas atmosphere with Mo as a target, to perform sputtering.

After deposition of the Mo thin film to be the back electrode, Cu_{c}A_{d}Te_{1-c-d} (where A is at least one element selected from a group consisting of Al, In and Ga) (c≦0.1, d≦0.1, or c+d≧0.9) is deposited by RF sputtering in such an amount that the coverage rate is not smaller than 0.1%, and is then heat-treated in ultra-high vacuum with a substrate temperature of the order of 500° C., thereby to form a crystal phase of Cu_{c}A_{d}Te_{1-c-d}. Thereafter, the Cu(Al_{1-a-b}InₐGa_{b})Te₂ thin film to be the light-absorbing layer is also deposited by RF sputtering to have a thickness of the order of 2 μm. x and y are numerical values larger than 0 and smaller than 1. RF power of 200 W is performed in the Ar-gas atmosphere, to form the film. After the film deposition, a film deposition chamber is evacuated and annealing is performed in an ultra-high vacuum atmosphere at 500° C. Although the Cu(Al_{1-a-b}InₐGa_{b})Te₂ thin film immediately after the deposition of sputtering is amorphous and has a very small grain size, annealing at high temperature leads to an increase in grain size of the Cu(Al_{1-a-b}InₐGa_{b})Te₂ thin film with the Cu_{c}A_{d}Te_{1-e-d} crystal phase acted as the crystal nucleus.

A ZnO thin film added with Mg was deposited as the buffer layer on the obtained absorbing layer, to have a thickness of the order of 50 nm. Although RF sputtering was used, it is preferably conducted with a power of 50 W in consideration of the plasma damage at the interface. Further, CdS can also be used for the buffer layer despite a large lattice mismatch with the Te chalcopyrite compound semiconductor film. A ZnO thin film is deposited as the semi-insulating layer on this buffer layer, and ZnO:Al containing 2-wt % alumina (Al₂O₃) to be the transparent electrode layer is deposited to have a thickness of the order of 1 μm. In addition to ZnO:Al, ZnO:B can also be used. As the lead-out electrode, Al, or NiCr and Au are deposited by the vapor evaporation method. Those are deposited so as to have a film thickness of the order of 300 nm. Finally, MgF₂ as the anti-reflective film is deposited by the sputtering method, to produce a compound thin film solar cell.

### Example 8

A compound thin film solar cell is manufactured in the same manner as in Example 7 except that Cu_{c}A_{d}Se_{1-c-d} (where A is at least one element selected from a group consisting of Al, In and Ga) (c≦0.1, d≦0.1, or c+d≧0.9) as a compound to be the crystal growth nucleus before deposition of the light-absorbing layer is deposited by RF sputtering.

In the case of depositing and annealing Cu_{c}A_{d}Se_{1-c-d} before deposition of the light-absorbing layer, an increase in grain size is promoted with Cu_{c}A_{d}Se_{1-c-d} acted as the crystal growth nucleus, so as to obtain a highly efficient compound thin film solar cell.

### Example 9

A compound thin film solar cell is manufactured in the same manner as in Example 7 except that Cu_{c}A_{d}S_{1-c-d} (where A is at least one element selected from a group consisting of Al, In and Ga) (y≦0.1, z≦0.1, or y+z≧0.9) as a compound to be the crystal growth nucleus before deposition of the light-absorbing layer is deposited by RF sputtering.

In the case of depositing and annealing Cu_{c}A_{d}S_{1-c-d} before deposition of the light-absorbing layer, an increase in grain size is promoted with Cu_{c}A_{d}S_{1-c-d} acted as the crystal growth nucleus, so as to obtain a highly efficient compound thin film solar cell.

### Example 10

A compound thin film solar cell is manufactured in the same manner as in Example 7 except that A_{c}Te_{1-c} (where A is at least one element selected from a group consisting of Al, In and Ga) (c≦0.1) as a compound to be the crystal growth nucleus before deposition of the light-absorbing layer is deposited by RF sputtering.

In the case of depositing and annealing A_{c}Te_{1-c} before deposition of the light-absorbing layer, an increase in grain size is promoted with A_{c}Te_{1-c} acted as the crystal growth nucleus, so as to obtain a highly efficient compound thin film solar cell.

### Example 11

A compound thin film solar cell is manufactured in the same manner as in Example 7 except that A_{c}Se_{1-c} (where A is at least one element selected from a group consisting of Al, In and Ga) (c≦0.1) as a compound to be the crystal growth nucleus before deposition of the light-absorbing layer is deposited by RF sputtering.

In the case of depositing and annealing A_{c}Se_{1-c} before deposition of the light-absorbing layer, an increase in grain size is promoted with A_{c}Se_{1-c} acted as the crystal growth nucleus, so as to obtain a highly efficient compound thin film solar cell.

### Example 12

A compound thin film solar cell is manufactured in the same manner as in Example 7 except that A_{c}S_{1-c} (where A is at least one element selected from a group consisting of Al, In and Ga) (c≦0.1) as a compound to be the crystal growth nucleus before deposition of the light-absorbing layer is deposited by RF sputtering.

In the case of depositing and annealing A_{c}S_{1-c} before deposition of the light-absorbing layer, an increase in grain size is promoted with A_{c}S_{1-c} acted as the crystal growth nucleus, so as to obtain a highly efficient compound thin film solar cell.

### Comparative Example 5

A compound thin film solar cell is manufactured in the same manner as in Example 7 except that the compound to be the crystal growth nucleus before deposition of the light-absorbing layer is not deposited.

In the case of not using the crystal nucleus, the crystal growth of the light-absorbing layer is not promoted and the grain size is thus not increased, thereby inhibiting the improved efficiency of the compound thin film solar cell.

The elements and atoms were written by means of element symbols.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A compound thin film solar cell, comprising as a light-absorbing layer a semiconductor thin film which contains Cu, an element A (A is at least one element selected from a group consisting of Al, In and Ga) and Te, and has a chalcopyrite crystal structure, wherein
a buffer layer that forms an interface with the light-absorbing layer is a compound which contains at least one element selected from Cd, Zn and a group consisting of In and Ga and at least one element selected from a group consisting of S, Se and Te, and has any crystal structure of a sphalerite structure, a wurtzite structure and a defect spinel structure, and
a lattice constant “a” of the buffer layer with the sphalerite structure or a lattice constant “a” of the buffer layer at the time of converting the wurtzite structure or the defect spinel structure to the sphalerite structure is not smaller than 0.59 nm and not larger than 0.62 nm.

2. The compound thin film solar cell according to claim 1, wherein a band gap of the buffer layer is larger than 2.3 eV and not larger than 2.7 eV.

3. The cell according to claim 1, wherein the lattice constant “a” of the buffer layer with the sphalerite structure or the lattice constant “a” of the buffer layer at the time of converting the wurtzite structure or the defect spinel structure to the sphalerite structure is larger than a lattice constant “a” of the light-absorbing layer.

4. The cell according to claim 1, wherein the buffer layer is either a compound of Zn(SₓTe₁₋ₓ) where x is larger than 0.8 and not larger than 1, or a compound of Zn(Te_{y}Se_{1-y}) where y is larger than 0.55 and not larger than 1.

5. A compound thin film solar cell, comprising as a light-absorbing layer a semiconductor thin film which contains Cu, an element A (A is at least one element selected from a group consisting of Al, In and Ga) and an element X (X is at least one element selected from a group consisting of S, Se and Te), and has a chalcopyrite crystal structure, wherein
an interfacial interlayer is formed at an interface between a back electrode and the light-absorbing layer,
a compound included in the interfacial interlayer contains a constitutional element of the back electrode and the element X of the light-absorbing layer, and
when an X-ray diffraction peak intensity from a (hkl) plane is referred to as Iₕₖₗ, an X-ray diffraction peak intensity ratio of the compound containing the constitutional element of the back electrode and the element X of the light-absorbing layer is 5>I₀₀₂/I₁₁₀>0.2.

6. The compound thin film solar cell according to claim 5, wherein the light-absorbing layer includes a compound semiconductor film of Cu(Al_{1-a-b}InₐGa_{b})(Te_{1-α}O_{α})₂ having the chalcopyrite crystal structure, and a band gap of the compound semiconductor film is not smaller than 1.0 eV and not larger than 1.5 eV.

7. The cell according to claim 5, wherein a compound included in the interfacial interlayer contains a constitutional element of the back electrode and the element X of the light-absorbing layer, and the interfacial interlayer has a thickness not larger than 1 μm.

8. A method for manufacturing a compound thin film solar cell, comprising the steps of:
forming a back electrode on a substrate;
forming a light-absorbing layer which includes a compound semiconductor thin film on the back electrode;
forming a buffer layer on the light-absorbing layer;
forming a semi-insulating layer on the buffer layer;
forming a transparent electrode layer on the semi-insulating layer;
forming a lead-out electrode on the back electrode;
forming a lead-out electrode on the transparent electrode layer; and
forming an interfacial interlayer at an interface between the back electrode and the light-absorbing layer, wherein
the light-absorbing layer is a semiconductor thin film which contains Cu, an element A (A is at least one element selected from a group consisting of Al, In and Ga) and an element X (X is at least one element selected from a group consisting of S, Se and Te), and has a chalcopyrite crystal structure,
a method for forming the light-absorbing layer is a sputtering method in the step of forming the light-absorbing layer, and
a method for forming the interfacial interlayer is heating treatment in the step of forming the interfacial interlayer.

9. A compound thin film solar cell, comprising as a light-absorbing layer a semiconductor thin film which contains Cu, an element A (A is at least one element selected from a group consisting of Al, In and Ga) and an element X (X is at least one element selected from a group consisting of S, Se and Te), and has a chalcopyrite crystal structure,
wherein at an interface between a back electrode and the light-absorbing layer, a crystal phase of Cu_{c}A_{d}X_{1-c-d} (A is at least one element selected from a group consisting of Al, In and Ga, X is at least one element selected from a group consisting of S, Se and Te, c is not larger than 0.1, and d is not smaller than 0.1, or c+d is not smaller than 0.9) is present.

10. The cell according to claim 9, wherein A of the light-absorbing layer and A of the crystal phase contain at least one identical element, and X of the light-absorbing layer and X of the crystal phase contain at least one identical element.

11. The cell according to claim 9, wherein the crystal phase covers 0.1% of an area where the light-absorbing layer on the back electrode is formed.

12. The cell according to claim 9, wherein the crystal phase has an average grain size not larger than 10 nm.

13. A method for manufacturing a compound thin film solar cell, comprising the steps of:
forming a back electrode on a substrate;
forming a light-absorbing layer which includes a compound semiconductor thin film on the back electrode;
forming a crystal phase of Cu_{c}A_{d}X_{1-c-d} (A is at least one element selected from a group consisting of Al, In and Ga, X is at least one element selected from a group consisting of S, Se and Te, c is not larger than 0.1, and d is not smaller than 0.1, or c+d is not smaller than 0.9) at an interface between the back electrode and the light-absorbing layer;
forming a buffer layer on the light-absorbing layer;
forming a semi-insulating layer on the buffer layer;
forming a transparent electrode layer on the semi-insulating layer;
forming a lead-out electrode on the back electrode;
forming a lead-out electrode on the transparent electrode layer; and
forming an interfacial interlayer at the interface between the back electrode and the light-absorbing layer.

14. The cell according to claim 13, wherein A of the light-absorbing layer and A of the crystal phase contain at least one identical element, and X of the light-absorbing layer and X of the crystal phase contain at least one identical element.

15. The cell according to claim 13, wherein the crystal phase covers 0.1% of an area where the light-absorbing layer on the back electrode is formed.

16. The cell according to claim 14, wherein the crystal phase has an average grain size not larger than 10 nm.
